(19) United States
(12) Patent Application Publication
(10) Pub. No.: US 2005/0180111 A1
(43) Pub. Date: Aug. 18, 2005

(54) Low thermal stress composite heat sink assembly

(76) Inventors: Brett E. Bamesberger, Colorado Springs, CO (US); Victor W. Ramsey, Colorado Springs, CO (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/780,943

(22) Filed: Feb. 18, 2004

(51) Int. Cl. H05K 7/20

(52) U.S. Cl. 361/704

(57) ABSTRACT

A heat sink assembly is presented for dissipating heat from one or more electronic components. The heat sink assembly may have a heat-dissipating substrate and one or more heat-dissipating studs, such that the one or more heat-dissipating studs may be within the heat-dissipating substrate such that the one or more electronic components may be attached to the one or more heat-dissipating studs.

### BACKGROUND OF THE INVENTION

Electronic components, such as integrated circuits or printed circuit boards, are becoming more and more common in various devices. For example, central processing units, interface, graphics and memory circuits typically comprise several integrated circuits. During normal operations, many electronic components, such as integrated circuits, generate significant amounts of heat in localized areas that are small relative to the overall assembly. If the heat generated during the operation of these and other devices is not removed, the electronic components or other devices near them may overheat, resulting in damage to the components or degradation of circuit performance.

In order to avoid such problems caused by over heating, heat sinks or other heat-dissipating devices are often used with electronic components to dissipate heat. In an assembly where the semiconductor die is mounted on the heat sink, the heat is primarily removed in a direction perpendicular to the surface of the die by a generally metallic heat sink that is attached to the die and other materials that have low coefficients of thermal expansion (CTE). Current practices are to make the entire heat sink of one material that has good heat conduction. Most materials currently used for heat sinks also have much larger coefficients of thermal expansion than semiconductor die or adjacent circuit elements. This may cause thermal stress and movement between the materials in the same plane as the die. These stresses and movements may damage the semiconductor die or otherwise reduce the electrical reliability of the die or electrical assembly.

Some prior solutions to this problem have been to select a heat sink material that compromises good heat conduction and the CTE mismatch between the die and the heat sink. This approach may limit the amount of heat that can be removed from the die. It also limits the overall circuit size due to the CTE mismatch between the die, printed circuit assembly (PCA) and the heat sink. Another disadvantage of this approach is that the typical materials used in this compromise tend to be uncommon, expensive and therefore difficult to shape and procure, e.g., CuW, aluminum carbide, and silicon carbide, which for example tend to require specialized processes and machining tooling to shape the heat sink.

One must balance the heat-dissipating requirements of a heat sink with other factors. Heat sinks may crack, damage or separate from the electronic components they are attached to if the heat sink has a coefficient of thermal expansion significantly different from the electronic component. Also, many heat sink materials are relatively heavy, If the electronic component the heat sink is attached to is subjected to vibration or impact, the weight of the heat sink attached to the electronic component may crack, damage or cause the heat sink to separate from the electronic component to which it is attached.

Some materials provide good thermal conductivity, but are difficult to shape, expensive, heavy or have other less desirable features to a particular heat-dissipating situation.

Accordingly, there exists a need in the industry for the ability to optimize heat dissipation, weight, cost, machinability and other features of a heat-dissipating device, while minimizing the CTE mismatch at the juncture between the electronic component being cooled and the heat-dissipating device.

### SUMMARY OF THE INVENTION

An apparatus and method for optimizing heat dissipation, CTE matching, weight, cost, machinability or other features of a heat dissipation device.

The apparatus comprises an heat sink device for dissipating heat from one or more electronic components, the heat sink device may have a heat-conducting substrate and one or more heat-conducting studs, such that the one or more heat-conducting studs may be within the heat-dissipating substrate such that the one or more electronic components may be attached to the one or more heat-conducting studs.

A method for manufacturing a specific heat sink device, which may include selecting or forming a heat-dissipating substrate with one or more apertures; forming one or more heat-conducting studs, such that the one or more heat-conducting studs may be shaped and sized to mate within the one or more apertures in the heat-dissipating substrate and mated with one or more electronic devices to be cooled.

### BRIEF DESCRIPTION OF THE DRAWINGS

A more complete appreciation of this invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 illustrates a side, cut-away view of a first embodiment of a heat-dissipating device;

FIG. 2 illustrates a top view of a first embodiment of a heat-dissipating device;

FIG. 3 illustrates a top view of another, rectangular embodiment of a heat-dissipating device;

FIG. 4 illustrates a side, cut-away view of another embodiment of a heat-dissipating device;

FIG. 5 illustrates a side, cut-away view of another embodiment of a heat-dissipating device;

FIG. 6 illustrates a side, cut-away view of another embodiment of a heat-dissipating device; and

FIG. 7 illustrates a flow chart for manufacturing a heat-dissipating device.

### DETAILED DESCRIPTION

As shown in the drawings for purposes of illustration, the present invention relates to techniques for providing a heat-dissipating device in which heat is conducted away from an electronic component, such as a semiconductor die in the direction needed, while thermal expansion stresses are minimized relative to the interface plane between the die and the heat-dissipating device.

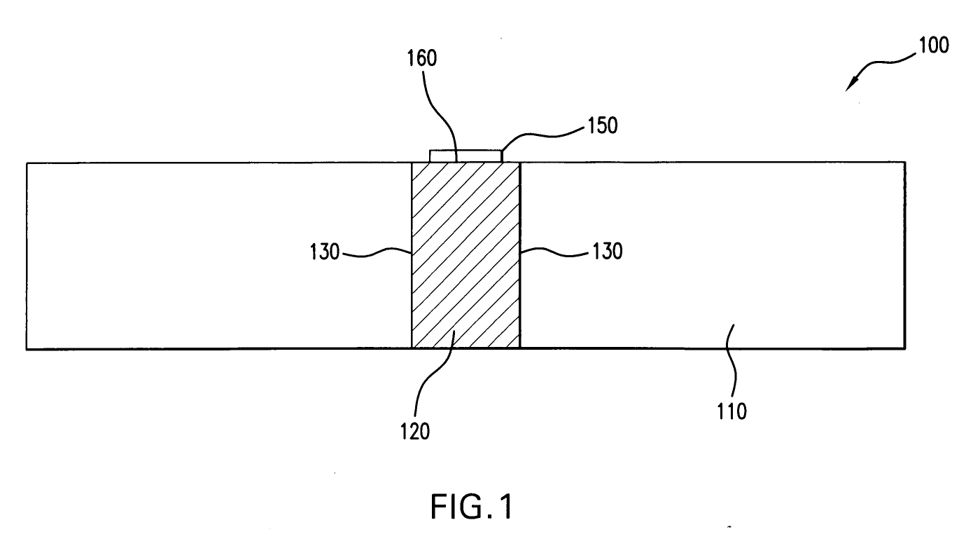

Turning now to the drawings, FIG. 1 illustrates a heat dissipation device according to a first embodiment of the present invention. A heat dissipation base 110 is provided. The heat dissipation substrate 110 may be selected from any known heat sink material, alloy or combination thereof, such as Aluminum Silicon Carbide, Copper, Aluminum, carbon/metal composite, ceramic, CuW, tungsten, aluminum carbide, silicon carbide or other known heat sink material. By way of example only, AlSiC may be selected for its heat conducting qualities and low weight. A heat-dissipating stud 120 may be formed by stamping, machining, etching or laser cutting from any known heat sink material, alloy or combination thereof, such as copper, tungsten, molybdenum, aluminum, copper/molybdenum/copper or other known heat sink material. Heat-dissipating stud 120 may be attached to the heat-dissipating base 110 by brazing, soldering, adhesive bonding, press fit, welding, cold diffusion under high pressure, diffusion bonding, thermally conductive or metallic adhesive or other similar method.

Heat stud 120 may be selected in order to have a CTE (coefficient of thermal expansion) that is relatively close to the circuit device 150 (integrated circuit die, integrated circuit package, integrated circuit module, printed circuit board, etc.) to which it is to be attached by conductive adhesive, solder paste, conductive epoxy, solder, inter-metallic bonding, eutectic die attach or other known die attach means. It should be noted, that the stud 120 may be attached to the device 150 to be cooled before the stud 120 is attached to the substrate 110.

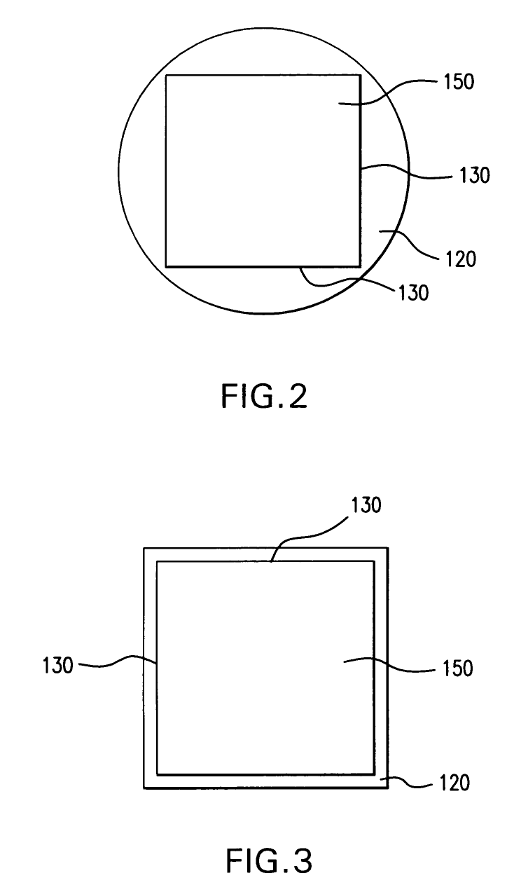

As shown in FIGS. 2 and 3, Heat stud 120 may be relatively cylindrical in shape, and then formed to fit the circuit at one end, as in FIG. 2 or having a relatively square or rectangular cross-section to align more closely with the shape of the circuit device 15, as in FIG. 3. It will be appreciated that the device 150 is attached to the stud 120 having similar expansion. Accordingly, heat is moved away from the device 150, while the thermal stresses are along the surface area 130 between the stud 120 and the base 110, rather than in the planes parallel to the device 150 and the stud. In this way, the selection of the base material may be done on a best match of CTE(s) of all the circuit and adjacent elements. Since the base is substantially removed from the heat path, its thermal conductivity is not a primary concern. The stud 120 and base 110 composite heat sink provides thermal transport perpendicular to the die and minimal thermal stresses parallel to the die.

The shear stress or movement that results from the CTE mismatch between the electronic device being cooled 150 and the heat-dissipating device have been effectively moved from the junction 160 between the device 150 and the heat sink 100 to the junction 130 between the stud 120 and the substrate 110 of the heat sink 100, where compressive stress represents less threat to the device 150, and in fact, may actually tighten the assembly of the components in the stud/substrate assembly. A heat sink assembly of this type may be manufactured with ordinary machine tools, such as mills, grinders and lathes from materials commonly available, such as aluminum, copper, kovar, silver, ceramic, metal oxides, refractory and plastics. Each material would be selected, in part, for best thermal conduction, or matching thermal expansion.

As the substrate 110 and the stud 120 are different materials, they may be electrically isolated, and thus, selective plating of the materials may be readily accomplished. Gold or other known plating materials may be applied to the areas that may most benefit from plating. For example, surfaces needing improved grounding performance at high frequencies or those that were more subject to corrosion if not plated.

Additionally, the stud 120 may be electrically isolated from the substrate 110 by means of a thin compliant elastomeric layer between the juncture 130 between the stud 120 and the substrate 110. The elastomer may help absorb CTE mismatch between the stud 120 and the substrate 110 and may help absorb movement of the stud 120 relative to the substrate 110 and reduce stress.

Also, multiple heat sinks may be made from a single billet base after a heat conductive core has been inserted. Thereafter, the basic heat sink machining process may be similar to that of a conventional heat sink. Multiple cores could also be inserted into single billet substrate lengths before parting off into thinner multiple heat sinks.

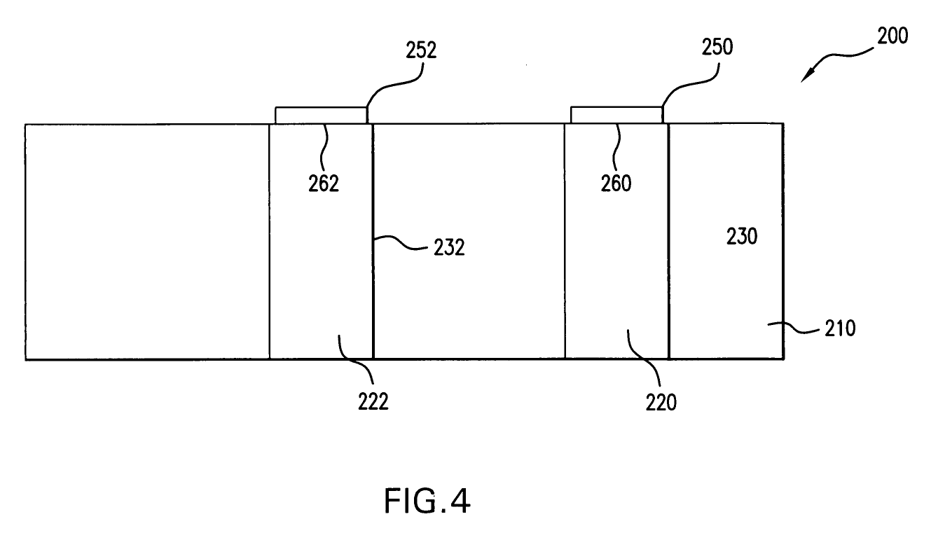

As shown in FIG. 4, more than one heat dissipation stud 220, 222 may be within the base 210. The use of more than one heat dissipation stud 220, 222 may be desirable in order to remove heat form different devices 250, 252 or different hot spots on a single device.

Where the substrate 110 and stud 120 are joined one unit at a time, application specific heat sinks may be made to optimize CTE matching between the stud 120 and the device 150 and thermal and other qualities of the heat-dissipating substrate 110 for a particular application. Alternatively, where the substrate and stud are joined one unit at a time, other core geometries may be possible. The stud may be any geometry, but may typically be substantially round, square or rectangular.

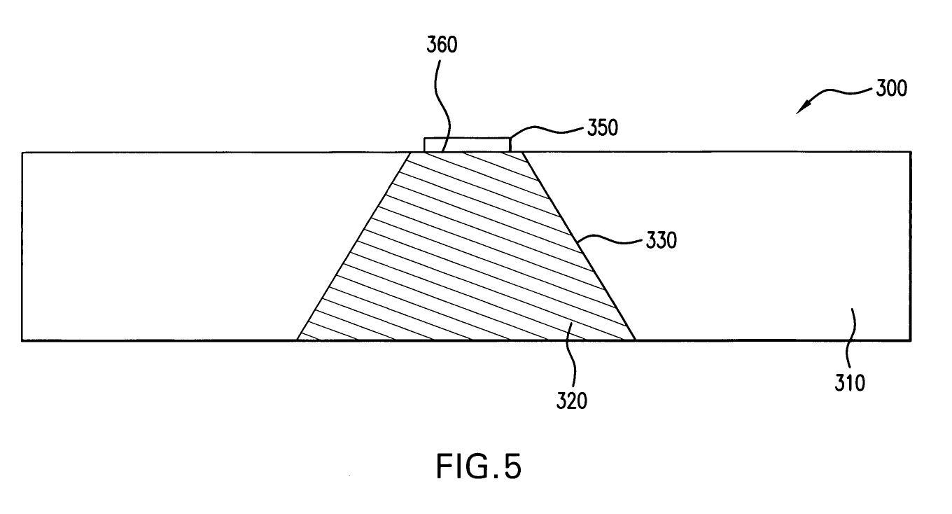

As shown in FIG. 5, an embodiment of a heat-dissipating device 300 may include a conical or pyramid shaped core 320 within a similarly shaped aperture within the heat-dissipating base 310. This design may be selected for further reduction of thermal gradients within the core of the heat-dissipating device 300.

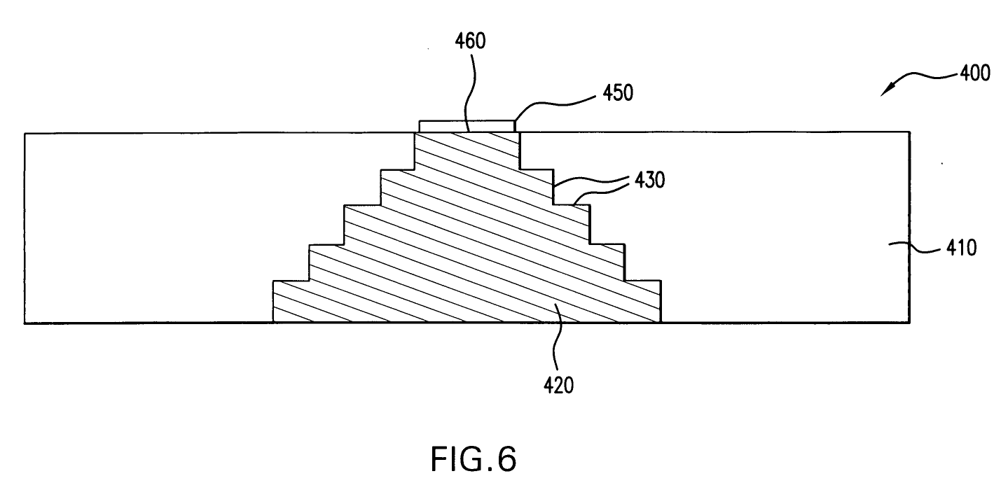

As shown in FIG. 6, an embodiment of a heat-dissipating device 400 may include a conical or pyramidal stepped core 420 within a similarly shaped aperture within the heat-dissipating base 410. The design may better retain or constrain the core 420 within the base.

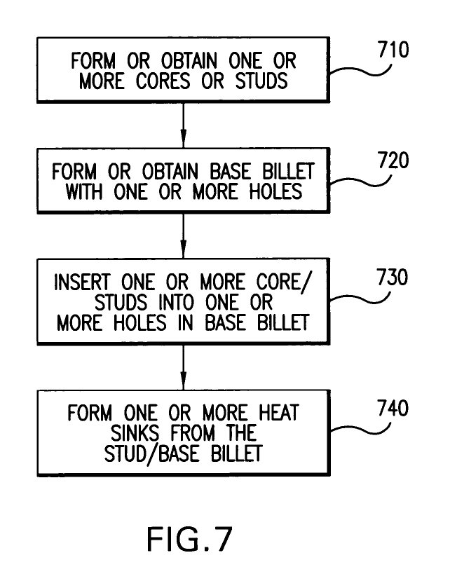

FIG. 7 illustrates a flow chart for manufacturing a heat-dissipating device according to the present invention. One or more heat-dissipating studs 120, 220, 222, 420, 520 may be chosen or formed 710 by means of stamping, machining, etching or laser cutting from any known heat sink material, alloy or combination thereof, such as copper, tungsten, molybdenum, aluminum, copper/molybdenum/copper or other known heat sink material. It should be noted that the material of the stud may be selected for CTE matching with the device to be cooled 150, 250, 252, 450, 550. One or more heat-dissipating bases 110, 210, 410, 510 is selected or formed 720 from any known heat sink material, alloy or combination thereof, such as Aluminum Silicon Carbide, Copper, Aluminum, carbon/metal composite, ceramic, CuW, tungsten, aluminum carbide, silicon carbide or other commonly known heat sink material with a lower CTE. The stud may be inserted into the base by pressing or casting or other known method 730. Alternatively, the aperture may be formed by machining, stamping or other known means and the stud may be inserted and mated therein by pressing, bonding, soldering brazing, soldering, adhesive bonding, diffusion bonding, cold diffusion under high pressure, a thermally conductive metallic adhesive or other known attachment means 730. One or more heat-dissipating devices 100, 200, 400, 500 may be formed 740 by conducting steps 710-730 on a large billet and then machining, cutting, etching or using other known separation means to create individual heat-dissipating devices from the larger billet. Steps 710-730 may be done to create individual heat-dissipating devices 100, 200, 400, 500 without the necessity of step 740.

Alternatively, the substrate may be formed or acquired 720 and then press or sinter one or more studs into the substrate 730. Also, an annular plastic elastomer may be formed between the stud and substrate by means of molding, casting, injecting or pressing to absorb and reduce thermal stresses and movement between the stud and substrate. Where multiple parts are made from one substrate billet, one or more studs and a substrate may be preassembled in lengths before individual heat sinks are parted off as thinner sections by means of turning, parting, shearing or cleaving,

Subsequent processing of the heat sinks might include machining of the stud(s) to accept square or multiple devices 150. The substrate may be milled down to lower a ceramic PCA or hybrid to the height of the device(s) 150. Selective plating of the substrate or stud may be done if desired. Where the substrate and stud are joined one unit at a time, these could be manufactured in a conventional machining process. Alternatively, the stud(s) may be cast or sintered into the aperture in the substrate.

Although this preferred embodiment of the present invention has been disclosed for illustrative purposes, those skilled in the art will appreciate that various modifications, additions and substitutions are possible, without departing from the scope of the invention, resulting in equivalent embodiments that remain within the scope of the appended claims. For example, the generic heat-dissipating substrate may also be a heat-dissipating substrate with fins or other common heat-dissipating physical features.

1. An heat sink device for dissipating heat from an electronic component, the heat sink device comprising:
an heat-dissipating substrate having one or more apertures; and
one or more heat-dissipating studs attached within said one or more apertures within said heat-dissipating substrate such that the electronic component may be attached to the heat-dissipating stud.

2. The application specific heat sink device in accordance with claim 1, wherein said one or more apertures in said heat-dissipating substrate extend from a first side to a second side of said heat-dissipating substrate.

3. The application specific heat sink device in accordance with claim 1, wherein said one or more apertures in said heat-dissipating substrate are cylindrical, conical or stepped.

4. The application specific heat sink device in accordance with claim 1, wherein said one or more apertures in said heat-dissipating substrate are pyramidal.

5. The application specific heat sink device in accordance with claim 1, wherein the heat-dissipating substrate includes fins.

6. The application specific heat sink device in accordance with claim 1, wherein the heat-dissipating stud comprises a material with a CTE relatively close to the CTE of the electronic component to be cooled.

7. The application specific heat sink device in accordance with claim 1, wherein the heat-dissipating stud comprises a material with a CTE relatively intermediate between the CTE of the electronic component to be cooled and the heat-dissipating substrate.

8. The application specific heat sink device in accordance with claim 1, wherein the heat-dissipating stud comprises a metal, a metal alloy or combinations thereof.

9. A method for manufacturing an heat sink device, comprising:
forming a heat-dissipating substrate with one or more apertures extending from a first surface to a second surface of the heat-dissipating substrate;
forming one or more heat-dissipating studs, wherein the one or more heat-dissipating studs are shaped and sized to mate within the aperture in the heat-dissipating substrate, extending from one side to the other of the aperture and mate with an electronic device to be cooled on one side of the aperture; and
attaching the heat-dissipating stud within the aperture of the substrate.

10. The method in accordance with claim 9, wherein the heat-dissipating stud comprises a material selected to have a relatively close CTE with the electronic device to be cooled.

11. The method in accordance with claim 9, wherein the heat-dissipating stud comprises a material selected to have an intermediate CTE between the heat-dissipating substrate and a device to be cooled.

12. The method in accordance with claim 9, further comprising the step of forming a cavity in a top surface of the heat-dissipating substrate; wherein the heat-dissipating stud is attached within the cavity formed on the heat-dissipating substrate.

13. The method in accordance with claim 9, wherein the heat-dissipating substrate includes fins.
